(19) United States
(12) Patent Application Publication
(10) Pub. No.: US 2025/0092267 A1
(43) Pub. Date: Mar. 20, 2025

(54) PHOTOCURABLE COMPOSITION

(71) Applicant: THREEBOND CO., LTD, Hachioji-shi, Tokyo (JP)

(72) Inventor: Chiaki MATSUI, Hachioji-shi, Tokyo (JP)

(21) Appl. No.: 18/577,008

(22) PCT Filed: Jul. 19, 2022
(86) PCT No.: PCT/JP2022/028009

§ 371 Date: Jan. 5, 2024

(30) Foreign Application Priority Data
Jul. 21, 2021 (JP) 2021-120077

(51) Int. Cl. C09D 4/06; C08F 255/10; C09D 151/00; G11B 33/14; H05K 5/06

(52) U.S. Cl. CPC C09D 4/06; C08F 255/10; C09D 151/003; H05K 5/061; C08F 2800/20; G11B 33/1466

(57) ABSTRACT

A photocurable composition exhibits favorable adhesion force to an adherend, and favorable durability upon compression of a cured product thereof. A photocurable composition contains the following components (A) to (D), component (A): a polyisobutylene compound having a (meth)acryloyl group in a molecule; component (B): a urethane-modified (meth)acrylate oligomer, excluding the component (A); component (C): a monomer having a (meth)acryloyl group, excluding the component (A) and the component (B); and component (D): a photoinitiator. A content of a monomer having an alicyclic structure and a (meth)acryloyl group is 6 to 20 mass % based on 100 mass % of a total amount of the component (C).

### TECHNICAL FIELD

The present invention relates to a photocurable composition.

### BACKGROUND ART

In the field of a hard disk drive, disturbance of air (wind disturbance) occurs and thereby vibration of a disk and a magnetic head is generated, and therefore a technique of inhibiting this malfunction by filling a housing with helium is commonly used as disclosed in Japanese Patent Laid-Open No. 2008-090886 (corresponding to U.S. Patent Laid-Open No. 2008/0088969). A sealing agent containing a polyisobutylene component having a (meth)acryloyl group in the molecule is known. However, this sealing agent has low adhesiveness to a lid of the hard disk drive, and specifically, peeling of an adhesion surface may occur in a durability test, resulting in leakage of helium.

### SUMMARY OF INVENTION

As noted above, an adhesion force of the conventional sealing agent using a polyisobutylene compound having a (meth)acryloyl group in the molecule to an adherend deteriorates, and it has been difficult to keep the adhesion force after compression of a cured product.

Accordingly, the present invention provides a photocurable composition that exhibits a favorable adhesion force to an adherend, and a favorable durability upon compression of a cured product thereof.

The present inventor has made intensive investigation to achieve the above object, and consequently found a method for improving an adhesion force of a photocurable composition containing a polyisobutylene compound having a polyisobutylene skeleton and a (meth)acryloyl group. This finding has led to completion of the present invention.

Hereinafter, the gist of the present invention will be described. A first aspect of the present invention is a photocurable composition comprising the following components (A) to (D), wherein a content of a monomer having an alicyclic structure and a (meth)acryloyl group is 6 to 20 mass % based on 100 mass % of a total amount of the component (c):
component (A): a polyisobutylene compound having a (meth)acryloyl group in a molecule;
component (B): a urethane-modified (meth)acrylate oligomer (excluding the component (A));
component (C): a monomer having a (meth)acryloyl group (excluding the component (A) and the component (B)); and
component (D): a photoinitiator.

A second aspect of the present invention is the photocurable composition according to the first aspect, wherein a total content of the component (B) is 1 to 50 parts by mass and a total content of the component (C) is 50 to 300 parts by mass, based on 100 parts by mass in total of the component (A).

A third aspect of the present invention is the photocurable composition according to the first or second aspect, wherein the alicyclic structure is a cyclic hydrocarbon group composed only of carbon atoms and hydrogen atoms.

A fourth aspect of the present invention is the photocurable composition according to any one of the first to third aspects, wherein the alicyclic structure is at least one group selected from the group consisting of an isobornyl group, a dicyclopentenyl group, and a dicyclopentanyl group.

A fifth aspect of the present invention is a cured product obtained by curing the photocurable composition according to any one of the first to fourth aspects with light irradiation.

A sixth aspect of the present invention is the cured product according to the fifth aspect, wherein a peak top temperature of tan δ in a dynamic viscoelasticity measurement is 0° C. or lower.

A seventh aspect of the present invention is a sealing agent comprising the photocurable composition according to any one of the first to fourth aspects.

An eighth aspect of the present invention is the sealing agent according to the seventh aspect, wherein the sealing agent is used for a hard disc drive cover seal.

### BRIEF DESCRIPTION OF DRAWINGS

FIG. 1 is a view illustrating a method for measuring an initial adhesion force. The reference 1 represents a bead, the reference 2 represents an adherend, the reference 3 represents a contact, and the reference 4 represents an advancing direction of the contact.

### DESCRIPTION OF EMBODIMENTS

A photocurable composition according to the present invention comprises the following components (A) to (D), wherein a content of a monomer having an alicyclic structure and a (meth)acryloyl group is 6 to 20 mass % based on 100 mass % of a total amount of the component (C):
component (A): a polyisobutylene compound having a (meth)acryloyl group in a molecule;
component (B): a urethane-modified (meth)acrylate oligomer (excluding the component (A));
component (C): a monomer having a (meth)acryloyl group (excluding the component (A) and the component (B)); and
component (D): a photoinitiator.

The photocurable composition of the present invention with such a configuration exhibits a favorable adhesion force to an adherend, and a favorable durability upon compression of a cured product thereof, and accordingly, the sealability can be improved.

Hereinafter, the present invention will be described in detail. The term (meth)acryloyl herein encompasses both of acryloyl and methacryloyl. Thus, for example, the term (meth)acryloyl group encompasses both of an acryloyl group and a methacryloyl group. Similarly, the term (meth)acryl encompasses both of acryl and methacryl.

The expression “X to Y” representing a range herein means a range including the lower limit (X) and the upper limit (Y) (X or more and Y or less).

### <Component (A)>

The component (A) contained in the photocurable composition according to the present invention is a polyisobutylene compound having a (meth)acryloyl group in the molecule. The polyisobutylene refers to a polymer having a polyisobutylene skeleton having a repeating unit represented by the following general formula 1. The repeating unit represented by the general formula 1 is also simply referred to as “polyisobutylene skeleton” herein. Here, the polymer refers to, without being limited by a theory, a compound having a structure with a repeating unit of a monomer in the molecule, such as a main chain, and having two or more of the repeating units, for example. The component (A) is not particularly limited as long as it has one or more (meth)acryloyl groups and is a compound having the polyisobutylene skeleton. The component (A) may be used singly, or may be used in combination of two or more. When two or more of the components (A) are used in combination, a content of the component (A) refers to a total amount thereof. A compound having a urethan bond in addition to the one or more (meth)acryloyl groups and the polyisobutylene skeleton is included in the compound (A), not included in the compound (B).

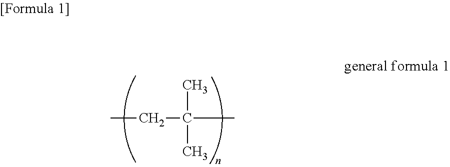

The number of the (meth)acryloyl groups in the component (A) is preferably 1 to 12, more preferably 2 to 8, further preferably 2 to 4, and from the viewpoint of curability, particularly preferably 2. The (meth)acryloyl group may be present at any of a side chain and a terminal of the molecule, but preferably present at a terminal of the molecule in terms of rubber elasticity.

In the component (A), a bonding form of the polyisobutylene skeleton is not particularly limited. The bonding form may be block or random, and is preferably block. In the general formula 1, “n” preferably represents 2 or more. The photocurable composition according to the present invention is estimated to have low permeability to water due to the polyisobutylene skeleton contained in the component (A). From the viewpoint of further improvement of the barrier property against water and adhesiveness, “n” in the general formula 1 more preferably represents 2 to 300, further preferably 10 to 150, and particularly preferably 20 to 100. The component (A) may have a structural unit other than the repeating unit represented by the general formula 1. When having the other structural unit, the component (A) may form a diblock form or a triblock form together with a block formed by polymerizing the other structural unit. That is, the component (A) may have a form (the diblock form or the triblock form) in which the block formed by polymerizing the other structural unit (polymerizable monomer) is further contained in addition to the block composed of the repeating unit represented by the general formula 1. Note that the component (A) preferably has a monoblock form having no block derived from the other polymerizable monomer and having only the block composed of the repeating unit represented by the general formula 1. From the viewpoint of more easily obtaining a cured product (improving curability) by introducing a rigid skeleton therein, the component (A) preferably has a polyisobutylene skeleton having an aromatic hydrocarbon group. The component (A) having the polyisobutylene skeleton having the aromatic hydrocarbon group can inhibit decrease in curability due to flexibility of the polyisobutylene skeleton in curing the photocurable composition. The aromatic hydrocarbon group may be contained at any of a main chain and a side chain of the component (A). From the viewpoint of improvement of curability of the photocurable composition, the aromatic hydrocarbon group is more preferably contained between the polyisobutylene skeleton and the (meth)acryloyl group present at the molecular terminal. Examples of an aromatic hydrocarbon ring contained in the aromatic hydrocarbon group include, but not particularly limited to, a benzene ring, a biphenyl ring, a naphthalene ring, a pentalene ring, an indene ring, a naphthalene ring, an anthracene ring, an azulene ring, a fluorene ring, a heptalene ring, an acenaphthalene ring, a phenalene ring, a phenanthrene ring, a triphenylene ring, a pyrene ring, a chrysene ring, a picene ring, a perylene ring, a pentaphene ring, a pentacene ring, a tetraphene ring, a hexaphene ring, and a hexacene ring. With considering easy availability, preferred is a benzene ring or a naphthalene ring, and particularly preferred is a benzene ring. That is, the aromatic hydrocarbon group is preferably a group derived from the above aromatic hydrocarbon group. From the viewpoint of further improvement of curability of the photocurable composition, the polybutylene skeleton preferably has a divalent aromatic hydrocarbon group. Here, the divalent aromatic hydrocarbon group is preferably an aromatic hydrocarbon group having 6 to 30 carbon atoms, more preferably a phenylene group, a biphenylene group, a naphthalenylene group, an anthrylene group, a fluorenylene group, a phenanthrylene group, or a pyrenylene group, further preferably a phenylene group, a biphenylene group, a naphthalenylene group, an anthrylene group, or a fluorenylene group, and particularly preferably a phenylene group. The aromatic hydrocarbon group may be substituted. The substituent is not particularly limited, and examples thereof include monovalent hydrocarbon groups having 1 to 20 carbon atoms and alkoxy groups having 1 to 20 carbon atoms. Examples of the monovalent hydrocarbon group having 1 to 20 carbon atoms include a methyl group, an ethyl group, a propyl group, an isopropyl group, a butyl group, a sec-butyl group, a tert-butyl group, a pentyl group, an isopentyl group, a neopentyl group, a hexyl group, an isohexyl group, a neohexyl group, a heptyl group, an octyl group, an isooctyl group, a sec-octyl group, a tert-octyl group, a 2-ethylhexyl group, a nonyl group, and a decanyl group. Examples of the alkoxy group having 1 to 20 carbon atoms include a methoxy group, an ethoxy group, a n-propyloxy group, an isopropyloxy group, a n-butoxy group, a sec-butoxy group, a tert-butoxy group, a n-pentyloxy group, an isopentyloxy group, a neopentyloxy group, a n-hexyloxy group, an isohexyloxy group, a neopentyloxy group, a n-heptyloxy group, a n-octyloxy group, an isooctyloxy group, a sec-octyloxy group, a tert-octyloxy group, a 2-ethylhexyloxy group, and a nonyloxy group.

A molecular weight of the component (A) is not particularly limited, but mainly from the viewpoint of excellent adhesiveness, the number average molecular weight is preferably 200 to 500,000, more preferably 500 to 400,000, furthermore preferably 1,000 to 100,000, and particularly preferably 3,000 to 50,000. As the number average molecular weight and a weight average molecular weight, a value calculated by a standard polystyrene conversion method using gel permeation chromatography (GPC) is used herein.

To lower permeability to water, a compound having a rubber skeleton, such as polybutadiene, hydrogenated polybutadiene, polyisoprene rubber, and hydrogenated polyisoprene, and having a (meth)acryloyl group is preferably substantially not contained in the molecule other than the component (A). The expression “substantially not contained” herein encompasses an aspect that the photocurable composition contains the substance of interest due to contamination, and means that the substance of interest may be present at a proportion of 0.1 mass % or less (lower limit: 0 mass %) based on the total amount of the photocurable composition.

As the component (A), any of commercial products and synthetic products may be used. A method for manufacturing the component (A) is not limited, and manufacturing methods described in Japanese Patent Laid-Open No. 2013-35901, Japanese Patent Laid-Open No. 2013-216782, National Publication of International Patent Application No. 2013-047314 (corresponding to U.S. Patent Laid-Open No. 2014/243444), International Publication No. WO 2017/099043 (corresponding to U.S. Patent Laid-Open No. 2018/362676), and the like may be appropriately applied. Specific examples of the commercially available component (A) include, but not limited to, EPION® Series EP400V, manufactured by KANEKA CORPORATION.

### <Component (B)>

The component (B) contained in the photocurable composition according to the present invention is a urethane-modified (meth)acrylate oligomer. Note that the component (B) does not include the component (A). That is, the component (B) is an oligomer having one or more urethane bonds and having one or more (meth)acryloyl groups in the molecule, and having no polyisobutylene skeleton. The oligomer herein refers to a substance having a weight average molecular weight of more than 1,000. The weight average molecular weight of the component (B) is preferably more than 1,000 and 200,000 or less, more preferably 5,000 to 100,000, and particularly preferably 10,000 to 50,000. Within such a range, an adhesiveness can be further improved. In addition, the component (B) lowers a permeability to an inert gas such as helium.

From the viewpoint of improvement of adhesiveness, the component (B) preferably has 2 to 10 (meth)acryloyl groups in one molecule, more preferably has 2 to 8 (meth)acryloyl groups, furthermore preferably has 2 to 4 (meth)acryloyl groups, and particularly preferably has two (meth)acryloyl groups. From the viewpoint of curability, the component (B) preferably has an acryloyl group.

Examples of a main skeleton of the component (B) include an ester bond, an ether bond, and a carbonate bond. It is known that the urethane-modified (meth)acrylate oligomers having these main skeletons can be obtained by, for example, a synthesis method of: forming a urethane bond by a reaction between a polyester polyol, a polyether polyol, or a polycarbonate polyol and a polyisocyanate, which are to become the main skeleton; and adding acrylic acid or a compound having a hydroxy group and a (meth)acryloyl group to the unreacted isocyanate group. The synthesis method is not limited thereto. From the viewpoint of improvement of adhesiveness, the main skeleton of the (B) is preferably an ester bond, an ether bond, or a carbonate bond, and particularly preferably an ether bond.

As the component (B), any of commercial products and synthetic products may be used. Specific examples of the commercially available component (B) include, but not limited to: AH-600, AT-600, UA-306H, and UF-8001G, manufactured by Kyoeisha Chemical Co., Ltd.; as the urethane-modified (meth)acrylate oligomer having a polyether skeleton, UN-6200, UN-6202, UN-6300, and UN-6301, manufactured by Negami Chemical Industrial Co., Ltd., and SHIKO® Series UV-2000B, UV-3300B, and UV-3700B, manufactured by Mitsubishi Chemical Corporation; as the urethane-modified (meth)acrylate oligomer having a polyester skeleton, UN-7600 and UN-7700, manufactured by Negami Chemical Industrial Co., Ltd.; and as the urethane-modified (meth)acrylate oligomer having a polycarbonate skeleton, UN-9000PEP and UN-9200A, manufactured by Negami Chemical Industrial Co., Ltd.

A content of the component (B) in the photocurable composition according to the present invention is preferably 1 to 50 parts by mass, more preferably 10 to 40 parts by mass, and most preferably 20 to 35 parts by mass, based on 100 parts by mass of the component (A). Containing the component (B) at 1 part by mass or more based on 100 parts by mass of the component (A) can keep a favorable adhesion force. Containing the component (B) at 50 parts by mass or less based on 100 parts by mass of the component (A) can effectively inhibit a separation from the component (A). The component (B) may be used singly, or may be used in combination of two or more. When a plurality of the components (B) is contained, the content of the component (B) means a total amount thereof.

### <Component (C)>

The component (C) contained in the photocurable composition according to the present invention is a monomer having a (meth)acryloyl group, and a monomer having one or more (meth)acryloyl groups. Note that the component (C) does not include the component (A) and the component (B). That is, the component (C) is a monomer having a (meth)acryloyl group other than the component (A) and the component (B). The component (C) contains a monomer having an alicyclic skeleton and a (meth)acryloyl group at 6 to 20 mass %, preferably 8 to 15 mass % based on the total amount of the component (C) being 100 mass %. Here, the alicyclic structure refers to a cyclic hydrocarbon group composed only of carbon atoms and hydrogen atoms. Examples of the alicyclic structure include, but not limited to: monocyclic cycloalkyl groups, such as a cyclopropyl group, a cyclobutyl group, a cyclopentyl group, a cyclohexyl group, a methylcyclohexyl group, and a dimethylcyclohexyl group; monocyclic cycloalkenyl groups, such as a cyclobutenyl group, a cyclopentenyl group, and a cyclohexenyl group; polycyclic cycloalkyl groups, such as a hydronaphthyl group, a 1-adamantyl group, a 2-adamantyl group, a norbornyl group, a methylnorbornyl group, an isobornyl group, a dicyclopentanyl group, a tricyclodecyl group, and a tetracyclododecyl group; and polycyclic cycloalkenyl groups, such as a dicyclopentenyl group and a dicyclopentenyloxyethyl group. An isobornyl group, a dicyclopentenyl group, and a dicyclopentanyl group are particularly preferable. When a plurality of the monomers having an alicyclic structure and a (meth)acryloyl group is contained, the above content means a total amount thereof.

A molecular weight of the component (C) is not particularly limited, but preferably 1000 or less, more preferably 500 or less, and further preferably 400 or less with considering dilution of the component (A) and the component (B). From the viewpoint of excellent compatibility with the component (A), the molecular weight of the component (C) is preferably 80 or more, more preferably 100 or more, and further preferably 150 or more. The molecular weight of the component (C) can be measured by known methods such as a gas chromatography mass spectrometry (GC-MS). Alternatively, the structure of the component (C) may be identified by a method such as NMR to specify the molecular weight with calculation based on the structure. The component (C) may be used singly, or may be used in combination of two or more.

The component (C) preferably has one to three (meth)acryloyl group(s). That is, the component (C) is preferably a monofunctional to trifunctional (meth)acrylate monomer. Furthermore, from the viewpoint of excellent compatibility with the component (A), it is more preferred that the component (C) contains a monofunctional (meth)acrylate monomer.

Specific examples of the monofunctional (meth)acrylate monomer include, but not limited to: (meth)acrylates having a chain structure, such as lauryl (meth)acrylate, isononyl (meth)acrylate, isooctyl (meth)acrylate, stearyl (meth)acrylate, 2-ethylhexyl (meth)acrylate, ethyl carbitol (meth)acrylate, methoxy diethylene glycol (meth)acrylate, ethoxy diethylene glycol (meth)acrylate, butoxyethyl (meth)acrylate, butoxy triethylene glycol (meth)acrylate, 2-ethylhexyl polyethylene glycol (meth)acrylate, methoxy dipropylene glycol (meth)acrylate, 2-hydroxyethyl (meth)acrylate, 2-hydroxypropyl (meth)acrylate, glycerol (meth)acrylate, polyethylene glycol (meth)acrylate, polypropylene glycol (meth)acrylate, ethylene-oxide-modified succinic acid (meth)acrylate, caprolactone-modified 2-hydroxyethyl (meth)acrylate, N,N-dimethylaminoethyl (meth)acrylate, and N,N-diethylaminoethyl (meth)acrylate; (meth)acrylates having an alicyclic structure, such as cyclohexyl (meth)acrylate, dicyclopentanyl (meth)acrylate, and isobornyl (meth)acrylate; (meth)acrylates having an aromatic ring structure, such as benzyl (meth)acrylate, phenyl (meth)acrylate, phenoxyethyl (meth)acrylate, phenoxy diethylene glycol (meth)acrylate, phenoxy tetraethylene glycol (meth)acrylate, nonylphenoxyethyl (meth)acrylate, nonylphenoxy tetraethylene glycol (meth)acrylate, nonylphenyl polypropylene glycol (meth)acrylate, nonylphenol EO-modified (meth)acrylate (n≈1), and ethylene-oxide-modified phthalic acid (meth)acrylate; (meth)acrylates having a heterocyclic structure, such as tetrahydrofurfuryl (meth)acrylate, caprolactone-modified tetrahydrofurfuryl (meth)acrylate, glycidyl (meth)acrylate, and morpholinoethyl (meth)acrylate; ethylene-oxide-modified phosphoric acid (meth)acrylate, and (meth)acryloylmorpholine.

Specific examples of the bifunctional (meth)acrylate monomer include, but not limited to: (meth)acrylates having a chain structure, such as 1,3-butylene glycol di(meth)acrylate, 1,4-butylene glycol di(meth)acrylate, neopentyl glycol di(meth)acrylate, 1,6-hexanediol di(meth)acrylate, ethylene glycol di(meth)acrylate, polyethylene glycol di(meth)acrylate, propylene glycol di(meth)acrylate, tripropylene glycol di(meth)acrylate, ethylene-oxide-modified neopentyl glycol di(meth)acrylate, propylene-oxide-modified neopentyl glycol di(meth)acrylate, hydroxypivalate ester neopentyl glycol di(meth)acrylate, caprolactone-modified hydroxypivalate ester neopentyl glycol di(meth)acrylate, neopentyl-glycol-modified trimethylolpropane di(meth)acrylate, and stearic-acid-modified pentaerythritol di(meth)acrylate; (meth)acrylates having an alicyclic structure, such as dimethyloltricyclodecane di(meth)acrylate, dicyclopentenyl di(meth)acrylate, and ethylene-oxide-modified dicyclopentenyl di(meth)acrylate; (meth)acrylates having an aromatic ring structure, such as bisphenol A di(meth)acrylate, ethylene-oxide-modified bisphenol A di(meth)acrylate, and ethylene-oxide-modified bisphenol S di(meth)acrylate; and (meth)acrylates having a heterocyclic structure, such as dimethacryloyl isocyanurate.

Specific examples of the trifunctional (meth)acrylate monomer include, but not limited to: (meth)acrylates having a chain structure, such as trimethylolpropane tri(meth)acrylate, pentaerythritol tri(meth)acrylate, ethylene-oxide-modified trimethylolpropane tri(meth)acrylate, and propylene-oxide-modified trimethylolpropane tri(meth)acrylate; and (meth)acrylates having a heterocyclic structure, such as tris(methacryloyloxyethyl) isocyanurate.

From the viewpoint of lowering of a viscosity of the photocurable composition to easily control the viscosity within an appropriate range, the component (C) preferably contains at least one selected from the group consisting of the monofunctional to trifunctional (meth)acrylate monomer having a chain structure, the monofunctional to trifunctional (meth)acrylate monomer having an aromatic ring structure, and the monofunctional to trifunctional (meth)acrylate monomer having a heterocyclic structure, in addition to the monofunctional to trifunctional (meth)acrylate monomer having an alicyclic structure. Specific example thereof include, but not limited to, in addition to the monofunctional (meth)acrylate monomer having an alicyclic structure such as isobornyl (meth)acrylate and dicyclopentanyl (meth)acrylate, monofunctional (meth)acrylate monomers having a chain hydrocarbon group (structure) such as isononyl (meth)acrylate, 2-ethylhexyl (meth)acrylate, and isooctyl (meth)acrylate, monofunctional (meth)acrylate monomers having an aromatic ring structure represented by the following general formula 2 such as nonylphenol EO-modified (meth)acrylate (n≈1) and paracumylphenol EO-modified (meth)acrylate (n≈1.2), and monofunctional (meth)acrylate monomers having a heterocyclic structure such as tetrahydrofurfuryl (meth)acrylate.

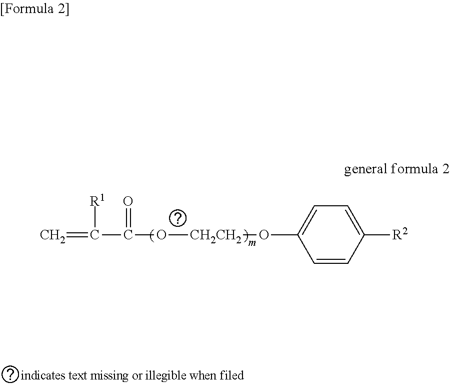

In the general formula 2, R¹ represents a hydrogen atom or a methyl group, R² represents a hydrocarbon group having 1 to 20 carbon atoms, and “m” represents an integer of 0 to 10.

In the general formula 2, R¹ further preferably represents a hydrogen atom. R² preferably represents a hydrocarbon group having 5 to 10 carbon atoms. Examples of the hydrocarbon group as R² include: saturated hydrocarbon groups, such as a methyl group, an ethyl group, a propyl group, an isopropyl group, a butyl group, a pentyl group, a hexyl group, a heptyl group, an octyl group, a nonyl group, an isononyl group, a decyl group, an undecyl group, a dodecyl group (lauryl group), a tridecyl group, a tetradecyl group, a pentadecyl group, a hexadecyl group, a heptadecyl group, and an octadecyl group (stearyl group); unsaturated hydrocarbon groups, such as a vinyl group, a 1-propenyl group, an allyl group, a 1-butenyl group, a 3-butenyl group, an isoprenyl group, a pentenyl group, a hexenyl group, a heptenyl group, an octenyl group, a nonenyl group, and a decenyl group; and aromatic hydrocarbon groups, such as a phenyl group, a naphthyl group, a biphenyl group, and a fluorenyl group. These substituents may be further substituted with one or more given different substituents. Note that the given substituent does not substitute the same type of the substituent. For example, a given substituent substituting an aromatic hydrocarbon group does not include an aromatic hydrocarbon group. R² particularly preferably represents a saturated hydrocarbon group having 5 to 10 carbon atoms.

In the general formula 2, “m” further preferably represents an integer of 0 to 3.

From the viewpoint of lowering of an outgas discharged from the cured product, the component (C) preferably contains the (meth)acrylate monomer represented by the general formula 2. From the same viewpoint, the component (C) more preferably contains the acrylate monomer represented by the general formula 2 (R¹ represents a hydrogen atom). In the (meth)acrylate monomer represented by the general formula 2, further preferable aspect of R¹ and “m” is as above. As the (meth)acrylate monomer being the component (C), any of commercial products and synthetic products may be used. Examples of specific trade names of the commercially available component (C) include, but not limited to: Light Ester IB-X, manufactured by Kyoeisha Chemical Co., Ltd.; INAA and IBXA, manufactured by OSAKA ORGANIC CHEMICAL INDUSTRY LTD.; SR440, manufactured by Arkema K.K.; 2-Ethylhexyl Acrylate, manufactured by Mitsubishi Chemical Corporation; ARONIX® M-111, M-110, and 2-Ethylhexyl Acrylate, manufactured by TOAGOSEI CO., LTD.; and FANCRYL® FA-513M and FA-513AS, manufactured by Showa Denko Materials Co., Ltd.

A content of the component (C) in the photocurable composition according to the present invention is preferably 50 to 300 parts by mass, more preferably 100 to 200 parts by mass, and further preferably 130 to 180 parts by mass based on 100 parts by mass of the component (A). Containing the component (C) at 50 parts by mass or more based on 100 parts by mass of the component (A) can lower a viscosity of the photocurable composition. Containing the component (C) at 300 parts by mass or less based on 100 parts by mass of the component (A) can effectively inhibit a separation from the component (A). When a plurality of the components (C) is contained, the content of the component (C) means a total amount thereof.

### <Component (D)>

The component (D) contained in the photocurable composition according to the present invention is a photoinitiator. The photoinitiator is a compound to generate a radical species by decomposition with light irradiation, and used for radial polymerization of the components (A) to (C). The component (D) may be used singly, or may be used in combination of two or more.

Specific examples of the photoinitiator of the component (D) include, but not limited to dimethoxyacetophenone, 1-hydroxycyclohexyl phenyl ketone, diethoxyacetophenone, acetophenone, propiophenone, benzophenone, xanthol, fluorene, benzaldehyde, anthraquinone, triphenylamine, 2,2-dimethoxy-1,2-diphenylethan-1-one, carbazole, 2-hydroxy-2-methylphenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)benzyl]phenyl}-2-methylpropan-1-one, 2-benzyl-2-dimethylamino-1-(4-morpholinophenyl)-1-butanone, bis(2,4,6-trimethylbenzoyl)phenylphosphine oxide, 2,4,6-teimethylbenzoyldiphenylphosphine oxide, 3-methylacetophenone, 4-methylacetophenone, 3-pentylacetophenone, 4-methoxyacetophenone, 3-bromoacetophenone, p-diacetylbenzene, 3-methoxybenzophenone, 4-allylacetophenone, 4-methylbenzophenone, 4-chloro-4-benzylbenzophenone, 3-chloroxanthone, 3,9-dichloroxanthone, 3-chloro-8-nonylxanthone, benzoyl, benzoin methyl ether, benzoin butyl ether, bis(4-dimethylaminophenyl) ketone, benzyl methoxy ketal, and 2-chlorothioxanthone. In addition, the examples also include oligomer/polymer-type photoinitiators such as 2-hydroxy-2-methyl-1-[4-(1-methylvinyl)phenyl]propanone oligomer and a polymer of 2-hydroxy-2-methyl-1-[4-(1-methylvinyl)phenyl]propanone (n=2 to 10). From the viewpoint of lowering of a outgas generated from the cured product, the component (D) particularly preferably includes an oligomer/polymer-type photoinitiator.

As the component (D), any of commercial products and synthetic products may be used. Specific examples of the commercially available component (D) include, but not limited to, oligomer-type polymerization initiators (oligomer/polymer-type photoinitiators) in which α-hydroxypropiophenone is bonded to a side chain, represented by ESACURE® KIP-150, manufactured by IGM Resin B.V.

A content of the component (D) in the photocurable composition according to the present invention is preferably 0.1 to 10 parts by mass, more preferably 1.0 to 5.0 parts by mass, and most preferably 3.0 to 5.0 parts by mass based on 100 parts by mass of the component (A). In the photocurable composition according to the present invention, containing the component (D) at 0.1 parts by mass or more based on 100 parts by mass of the component (A) exhibits an optimal handling property. Containing the component (D) at 10 parts by mass or less based on 100 parts by mass of the component (A) can keep a favorable curability. When a plurality of the components (D) is contained, the content of the component (D) means a total amount thereof.

### <Other Components>

The photocurable composition according to the present invention may further contain components other than the components (A) to (D) within a range not impairing the characteristics of the present invention. Examples of such components include reactive monomers other than the components (A) to (C), coloring agents such as a pigment and a dye, inorganic fillers such as silica, metal powder, calcium carbonate, talc, alumina, and aluminum hydroxide, organic fillers such as a polystyrene filler, a polyurethane filler, a poly(meth)acryl filler, and a rubber filler, organic peroxides, plasticizers, flame retardants, antioxidants, polymerization inhibitors, defoamers, coupling agents, leveling agents, and rheology controllers. Addition of these other components yields composition and its cured product having excellent resin strength, adhesion strength, operability, and storability. A content of the other components is not particularly limited, and a person skilled in the art may appropriately set the content within the range not impairing the characteristics of the present invention.

Examples of the reactive monomers other than the components (A) to (C) include: acrylic acid; methacrylic acid; and (meth)acrylamide compounds, such as (meth)acrylamide, N-methyl(meth)acrylamide, N-ethyl(meth)acrylamide, N-propyl(meth)acrylamide, N-isopropyl(meth)acrylamide, N-n-butyl(meth)acrylamide, N-tert-butyl(meth)acrylamide, N-butoxy methyl(meth)acrylamide, N-methylol(meth)acrylamide, N,N-dimethyl(meth)acrylamide, 4-(meth)acryloylmorpholine, N,N-diethyl(meth)acrylamide, N-methyl-N-ethyl(meth)acrylamide, and N-hydroxyethyl(meth)acrylamide.

As the inorganic filler, those known in the present technical field may be used, and hydrophilic silica in which silanol groups are remained on the surface is particularly preferably used. Using the hydrophilic silica in combination with the components (A) to (C) can contribute to an achievement and a stabilization of both of further lower viscosity and high structural viscosity ratio. Since the component (A) and the hydrophilic silica have polarity different from each other, a preferable thixotropy can be imparted to the photocurable composition. Among silica, amorphous silica is particularly suitable. The amorphous silica is hydrophilic silica powders (particles) having an average primary particle diameter of 1 to 100 nm and a specific surface area by a BET method of 10 to 300 m²/g. As the average primary particle diameter, a value measured from a scanning electron microscopic image of the measurement target by using an image analysis software and the like is adopted herein. Specifically, a statistically reliable predetermined number of particles (for example, total 1000 or more in 100 particles×10 planes per observation field) are observed, and the analysis software is used to obtain a particle image and calculate the particle diameter. As the inorganic filler, any of commercial products and synthetic products may be used. Specific examples of the commercially available inorganic filler include, but not limited to, AEROSIL® Series OX50, 50, 90G, 130, 150, 200, 300, and 380, manufactured by NIPPON AEROSIL CO., LTD. When the photocurable composition according to the present invention contains the inorganic filler, a content of the inorganic filler is preferably 0.1 to 50 parts by mass, more preferably 1 to 30 parts by mass, and most preferably 5 to 25 parts by mass based on 100 parts by mass of the component (A). Containing the inorganic fillers at 0.1 parts by mass or more based on 100 parts by mass of the component (A) can keep a high structural viscosity ratio, and containing the inorganic filler at 50 parts by mass or less based on 100 parts by mass of the component (A) yields a favorable handling property.

The organic peroxide refers to an organoperoxide. Containing the organic peroxide in the photocurable composition according to the present invention can cure an uncured portion by heating, which was not irradiated with light in light irradiation. Specific examples of the organic peroxide include, but not limited to: ketone peroxides, such as methyl ethyl ketone peroxide, cyclohexanone peroxide, 3,3,5-trimethylcyclohexanone peroxide, methylcyclohexanone peroxide, methyl acetoacetate peroxide, and acetylacetone peroxide; peroxyketals, such as 1,1-bis(t-butylperoxy)-3,3,5-trimethylcyclohexane, 1,1-bis(t-butylperoxy)cyclohexane, 2,2-bis(t-butylperoxy)octane, n-butyl-4,4-bis(t-butylperoxy) valerate, and 2,2-bis(t-butylperoxy)butane; hydroperoxides, such as t-butyl hydroperoxide, cumene hydroperoxide, diisopropylbenzene hydroperoxide, p-menthane hydroperoxide, 2,5-dimethylhexane-2,5-dihydroperoxide, and 1,1,3,3-tetramethylbutyl hydroperoxide; dialkyl peroxides, such as di-t-butyl peroxide, t-butyl cumyl peroxide, dicumyl peroxide, α,α′-bis(t-butylperoxy-m-isopropyl)benzene, 2,5-dimethyl-2,5-di(t-butylperoxy)hexane, and 2,5-dimethyl-2,5-di(t-butylperoxy)hexyne-3; diacyl peroxides, such as acetyl peroxide, isobutylyl peroxide, octanoyl peroxide, decanoyl peroxide, lauroyl peroxide, 3,5,5-trimethylhexanoyl peroxide, succinic acid peroxide, benzoyl peroxide, 2,4-dichlorobenzoyl peroxide, and m-tolyloyl peroxide; peroxy dicarbonates, such as diisopropyl peroxy dicarbonate, di-2-ethylhexyl peroxy dicarbonate, di-n-propyl peroxy dicarbonate, bis(4-t-butylcyclohexyl)peroxy dicarbonate, dimyristyl peroxy dicarbonate, di-2-ethoxyethyl peroxy dicarbonate, dimethoxyisopropyl peroxy dicarbonate, di(3-methyl-3-methoxybutyl) peroxy dicarbonate, and diallyl peroxy dicarbonate; peroxy esters, such as t-butyl peroxyacetate, t-butyl peroxyisobutyrate, t-butyl peroxypivalate, t-butyl peroxyneodecanoate, cumyl peroxyneodecanoate, t-butyl peroxy-2-ethylhexanoate, t-butyl peroxy-3,5,5-trimethylhexanoate, t-butyl peroxylaurate, t-butyl peroxybenzoate, di-t-butyl peroxyisophthalate, 2,5-dimethyl-2,5-di(benzoylperoxy)hexane, t-butyl peroxymaleic acid, t-butyl peroxy isopropylcarbonate, cumyl peroxyoctoate, t-hexyl peroxyneodecanoate, t-hexyl peroxypivalate, t-butyl peroxyneohexanoate, t-hexyl peroxyneohexanoate, and cumyl peroxyneohexanoate; and acetyl cyclohexylsulfonyl peroxide, and t-butyl peroxy allylcarbonate. A content of the organic peroxide is not particularly limited, and a person skilled in the art may appropriately set the content within a range not impairing the characteristics of the present invention. The organic peroxide may be used singly, or may be used in combination of two or more.

The plasticizer is a non-reactive compound. Here, the term “non-reactive” means that no reaction would occur with the components (A) to (C) in the present invention. Specific examples of the plasticizer include, but not limited to: as polycarboxylate ester plasticizers, an aromatic polycarboxylate ester; as phthalate ester plasticizers, dioctyl phthalate (DOP), dibutyl phthalate (DBP), diheptyl phthalate (DHP), diisononyl phthalate (DINP), diisodecyl phthalate (DIDP), and butyl benzyl phthalate (BBP); as trimellitate ester plasticizers, trioctyl trimellitate (TOTM) and triisodecyl trimellitate (TITM); as pyromellitate ester plasticizers, tetraoctyl pyromellitate; as aliphatic polycarboxylate ester plasticizers, di-2-ethylhexyl adipate (DOA), isodecyl adipate (DIDA), di-2-ethylhexyl sebacate (DOS), dibutyl sebacate (DBS), di-2-ethylhexyl maleate (DOM), dibutyl fumarate (DBF), di-2-ethylhexyl azelate (DOZ), di-2-ethylhexyl epoxyhexahydrophthalate, trioctyl citrate, and glycerol triacetate; as phosphate ester plasticizers, trimethyl phosphate, tributyl phosphate, tri-(2-ethylhexyl) phosphate, tributoxyethyl phosphate, triphenyl phosphate, tricresyl phosphate, an alkyl aryl phosphate, triethyl phosphate, tri(chloroethyl) phosphate, trisdichloropropyl phosphate, tris(β-chloropropyl) phosphate, octyl diphenyl phosphate, tris(isopropylphenyl) phosphate, and cresyl phenyl phosphate. These plasticizers may be used singly, or may be used in combination of two or more.

As the non-reactive plasticizer, an elastomer may also be used. Such a plasticizer is preferably an elastomer which is a liquid form at 25° C. Specific examples of the non-reactive elastomer include rubber elastomers, such as polybutadiene, hydrogenated polybutadiene, polyisoprene, hydrogenated polybutadiene, polybutene, polyisobutylene, a copolymer thereof, a diblock copolymer thereof, and a triblock copolymer thereof. Examples of the block copolymer include, but limited to, polystyrene-polyisobutylene diblock copolymer and polystyrene-polyisobutylene-polystyrene triblock copolymer. This component preferably has compatibility with the components (A) to (C). These may be used singly, or may be used in combination of two or more.

A viscosity (conditions: measurement temperature of 25° C. and shearing rate of 20 s⁻¹) of the photocurable composition according to the present invention is not particularly limited, but preferably 3 to 40 Pa·s, more preferably 3 to 35 Pa-s, and further preferably 5 to 30 Pa·s from the viewpoints of operability and the like. When a viscosity with a shearing rate of 20 s⁻¹ is specified as a viscosity 1 and a viscosity with a shearing rate of 2 s⁻¹ is specified as a viscosity 2, a value of the viscosity 2/the viscosity 1 (structural viscosity ratio or thixotropic ratio) is also not limited, but preferably 3.0 to 6.0, more preferably 3.5 or more and less than 5.5, and further preferably 4.0 to 5.4. Unless otherwise mentioned, the value of the viscosity herein is a value measured at 25° C. by using a corn-plate rheometer.

Another aspect of the present invention relates to a cured product obtained by curing the above photocurable composition with light irradiation. The cured product according to an aspect of the present invention is preferably cured by irradiating the above photocurable composition with active energy ray such as ultraviolet ray. More specifically, the cured product according to an aspect of the present invention is preferably obtained by applying the above photocurable composition on an adherend, and then irradiating the applied composition with the active energy ray.

A method for applying the photocurable composition according to the present invention on an adherend is not particularly limited. For example, methods such as dispensing using an automatic applicator, spraying, ink jet, screen printing, gravure printing, dipping, spin coating may be used.

The photocurable composition according to the present invention can be cured by irradiation with the active energy ray (for example, light such as ultraviolet ray and visible light). A light source used in this time is not particularly limited, and known light sources may be used. Examples of the light source include a low-pressure mercury lamp, a high-pressure mercury lamp, an ultrahigh-pressure mercury lamp, a blacklight lamp, a sodium lamp, a halogen lamp, a xenon lamp, and an LED. As an apparatus to cure the photocurable composition according to the present invention with irradiation with the active energy ray (light irradiation), an irradiation apparatus having the above light source may be used. Specific examples of this apparatus include, but not limited to, a belt-conveyer-type irradiation apparatus and a spot irradiation apparatus. A lower limit of an accumulated light quantity is not particularly limited, but preferably 20 kJ/m² or more, and more preferably 30 kJ/m² or more. An upper limit of the accumulated light quantity is also not particularly limited, but preferably 80 kJ/m² or less, and more preferably 70 kJ/m² or less.

The photocurable composition according to the present invention can keep a favorable adhesion force to an adherend, and therefore, suitably used for use of a hard disc drive cover seal. Specifically, the photocurable composition according to the present invention can prevent a leakage of an inert gas such as helium inside the housing toward an outside environment and a penetration of water from the outside environment also can be prevented even if a planarity, a shape and a size of the lid change.

### EXAMPLES

Next, the present invention will be described in more detail with Examples, but the present invention is not limited to only these Examples. Hereinafter, a photocurable composition is also simply referred to as a composition.

### Examples 1 to 5, Comparative Examples 1 to 4, and Reference Example 1

For preparing compositions, the following components were prepared:

Component (A): Polyisobutylene compound having a (meth)acryloyl group in the molecule
Acrylate compound having a polyisobutylene skeleton (manufactured by KANEKA CORPORATION, EPION® EP400V)
   Component (B): Urethane-modified (meth)acrylate oligomer (excluding the component (A))
UV-curable urethane acrylate having a polyether main skeleton (manufactured by Mitsubishi Chemical Corporation, SHIKO® UV-3700B)
   Component (C): (Meth)acrylate monomer (excluding the component (A) and the component (B))
   Component (C-1): Monomer having an alicyclic structure and an acryloyl group
Isobornyl methacrylate (manufactured by Kyoeisha Chemical Co., Ltd., Light Ester IB-X)
Isobornyl acrylate (manufactured by OSAKA ORGANIC CHEMICAL INDUSTRY LTD., IBXA)
Dicyclopentanyl methacrylate (manufactured by Showa Denko Materials Co., Ltd., FANCRYL® FA-513M)
Dicyclopentanyl acrylate (manufactured by Showa Denko Materials Co., Ltd., FANCRYL® FA-513AS)
   Component (C-2): Monomer having a (meth)acryloyl group other than the component (C-1)
Isononyl acrylate (manufactured by OSAKA ORGANIC CHEMICAL INDUSTRY LTD., INAA)
Nonylphenol EO-modified acrylate (n≈1) (manufactured by TOAGOSEI CO., LTD., ARONIX® M-111)
Tetrahydrofurfuryl acrylate (manufactured by Kyoeisha Chemical Co., Ltd., Light Acrylate THF-A)
Acryloylmorpholine (manufactured by KJ Chemicals Corporation, ACMO)
Cyclizing-polymerizable monomer having an acryloyl group and an allyl ether (manufactured by NIPPON SHOKUBAI CO., LTD., AOMA®)
   Component (D): photoinitiator
Oligomer of 2-hydroxy-2-methyl-1-[4-(1-methylvinyl)phenyl]propane (manufactured by IGM Resins B.V., ESACURE® KIP-150)

### Inorganic Filler

Hydrophilic amorphous silica with average primary particle diameter: 12 nm and specific surface area (BET method): 200 m²/g (manufactured by NIPPON AEROSIL CO., LTD., AEROSIL® 200)

The above components (A) to (D) were weighed and fed into a mixer, and the mixture was stirred for 30 hours. Thereafter, the inorganic filler was weighed and fed into the mixer, and the mixture was further stirred for 30 hours with defoaming in vacuum. Details of the prepared amount are shown in the following Table 1. Units of values in the following Table 1 are all “parts by mass” unless otherwise specified. Blanks in the following Table 1 represent that the component is not used.

TABLE 1

| | | Raw | Example | Example | Example | Example | Example | Comparative |
|---|---|---|---|---|---|---|---|---|
| Component | | material | 1 | 2 | 3 | 4 | 5 | Example 1 |
| Component (A) | | EP400V | 100.0 | 100.0 | 100.0 | 100.0 | 100.0 | 100.0 |
| Component (B) | | UV-3700B | 27.4 | 27.4 | 27.4 | 27.4 | 27.4 | 27.4 |
| Component | Component | IB-X | 16.4 | 12.3 | | | | |
| (C) | (C-1) | IBXA | | | 16.4 | | | |
| | | FA-513M | | | | 16.4 | | |
| | | FA-513AS | | | | | 16.4 | |
| | Component | INAA | 61.6 | 61.6 | 61.6 | 61.6 | 61.6 | 61.6 |
| | (C-2) | M-111 | 68.5 | 68.5 | 68.5 | 68.5 | 68.5 | 68.5 |
| | | THF-A | | 4.1 | | | | 16.4 |
| | | ACMO | | | | | | |
| | | ACMA | | | | | | |

| | | | | | | | |
|---|---|---|---|---|---|---|---|
| Component (D) | KIP-150 | 4.1 | 4.1 | 4.1 | 4.1 | 4.1 | 4.1 |
| Inorganic filler | 200 | 21.9 | 21.9 | 21.9 | 21.9 | 21.9 | 21.9 |

| | | | | | | |
|---|---|---|---|---|---|---|
| Total | 299.9 | 299.9 | 299.9 | 299.9 | 299.9 | 299.9 |
| Total of components (C) | 146.5 | 146.5 | 146.5 | 146.5 | 146.5 | 146.5 |
| Total of components (C-1) | 16.4 | 12.3 | 16.4 | 16.4 | 16.4 | 0.0 |
| Proportion (%) of component | 11.2 | 8.4 | 11.2 | 11.2 | 11.2 | 0.0 |
| (C-1) in component (C) | | | | | | |

| | | Raw | Comparative | Comparative | Comparative | Reference |
|---|---|---|---|---|---|---|
| Component | | material | Example 2 | Example 3 | Example 4 | Example 1 |
| Component (A) | | EP400V | 100.0 | 100.0 | 100.0 | 100.0 |
| Component (B) | | UV-3700B | 27.4 | 27.4 | | 27.4 |
| Component | Component | IB-X | 8.2 | | 16.4 | |
| (C) | (C-1) | IBXA | | | | |
| | | FA-513M | | | | |
| | | FA-513AS | | | | |
| | Component | INAA | 61.6 | 61.6 | 61.6 | 61.6 |
| | (C-2) | M-111 | 68.5 | 68.5 | 68.5 | 68.5 |
| | | THF-A | 8.2 | | | |
| | | ACMO | | | | 16.4 |
| | | ACMA | | 16.4 | | |

| | | | | | |
|---|---|---|---|---|---|
| Component (D) | KIP-150 | 4.1 | 4.1 | 4.1 | 4.1 |
| Inorganic filler | 200 | 21.9 | 21.9 | 21.9 | 21.9 |

| | | | | |
|---|---|---|---|---|
| Total | 299.9 | 299.9 | 272.5 | 299.9 |
| Total of components (C) | 146.5 | 146.5 | 146.5 | 146.5 |
| Total of components (C-1) | 8.2 | 0.0 | 16.4 | 0.0 |
| Proportion (%) of component | 5.6 | 0.0 | 11.2 | 0.0 |
| (C-1) in component (C) | | | | |

Of the compositions of Examples 1 to 5, Comparative Examples 1 to 4, and Reference Example 1, appearance (before curing and after curing) observation, determination of thick-film curability, measurement of initial adhesion force, measurement of adhesion force after durability, and DMA measurement (dynamic viscoelasticity measurement) were performed by the following methods. The results are summarized in the following Table 2.

[Appearance (Before Curing and after Curing) Determination]

Into a test tube, 10 g of the composition was sampled, light was shielded, and left to stand for three days under an atmosphere at 25° C. The appearance was visually observed in accordance with the following evaluation criteria to evaluate as “Appearance (before curing)”. In this evaluation, “transparent” or “milky white” are preferable, and as for “separation”, other evaluations were not performed to describe as “-”. Thereafter, the compositions other than “separation” was cured by irradiation with ultraviolet ray (wavelength: 365 nm) so that an accumulated light quantity was 60 kJ/m² by using a high-pressure mercury lamp with a belt-conveyer-type ultraviolet ray irradiation apparatus. Thereafter, the obtained cured product was visually observed to evaluate as “Appearance (after curing)”

### [Viscosity and Thixotropic Ratio]

By using a corn-plate rheometer, a viscosity and a thixotropic ratio were measured with the following measurement specifications. As the corn-plate rheometer, HAAKE MARS III, manufactured by Thermofisher Scientific Inc., was used.

A viscosity with a shearing rate of 20 s⁻¹ was specified as a viscosity 1, and a viscosity with a shearing rate of 2 s⁻¹ was specified as a viscosity 2. A value of the viscosity 1 is represented in “Viscosity (Pa·s)”, and a value of the viscosity 2/the viscosity 1 is represented in “Thixotropic ratio”.

### Measurement Specification

Atmosphere temperature during measurement: 25° C.

Corn: C35/2 (angle: 2°)

### [Determination of Thick-Film Curability]

In a state where the composition was added to 10 mm in depth in a glass container with 2 cm in diameter, the composition was irradiated with ultraviolet ray (wavelength: 365 nm) so that an accumulated light quantity was 60 kJ/m² by using a high-pressure mercury lamp with a belt-conveyer type irradiation apparatus. An uncured product was wiped off, and a thickness of the cured product was measured with a caliper to specify this value as “Thick-film curability (mm)”. The thick-film curability is preferably 5 mm or more for a sealing agent use.

### [Measurement of Initial Adhesion Force]

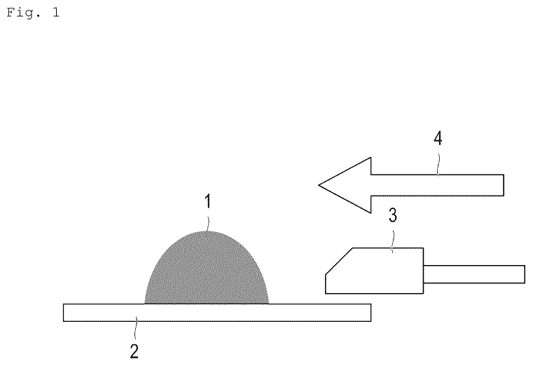

On a plate made of SUS 304 as an adherend, the composition was applied with a dispenser in a bead shape with 3.0±0.15 mm in width, 2.0±0.2 mm in height, and 10 mm in length. The composition was irradiated at an accumulated light quantity of 60 kJ/m² using a high-pressure mercury lamp with a belt-conveyer-type irradiation apparatus, and heated with a hot-blow drying furnace under baking conditions of 150° C.×3 hours to produce a test piece. After the baking, the test piece was left to stand overnight under a room temperature environment, and then a digital force gauge equipped with a contactor (the tip had a width of 10 mm and the height of 2 mm) manufactured by Nippon Densan Corporation was moved at a speed of 50 mm/min as illustrated in FIG. 1. A bottom of the contact was positioned with 0.2 mm from the adherend, and the bead was pushed from a just side thereof to specify a maximum load at this time as “Initial strength (N)”. The initial strength is preferably 7.0 N or more. After the measurement of the adhesion force, a state of peeling the bead from the adherend was visually observed, and evaluated as “Initial peeling state” under the following evaluation criteria. With considering leakage on the interface, the initial peeling state is preferably “Excellent” or “Good”.

### Evaluation Criteria of Initial Peeling State

Excellent: cohesive failure on entire surface

Good: cohesive failure on entire surface but partial interfacial failure

Poor: interfacial failure on entire surface

[Measurement of Adhesion Force after Durability]

On the test piece produced in the measurement of initial adhesion force, the bead was pressed and compressed to 60% of the bead height with a plate made of SUS 304, and left under an atmosphere at 100° C. for one week in a hot-blow drying furnace. In a state returned to room temperature, the strength was measured in the same manner as in the initial adhesion force to specify the strength as “Strength after durability (N)”, and “Rate of change (%)” was calculated from (Strength after durability−Initial strength)/Initial strength×100. To keep the sealability characteristics of the cured product, the strength after durability is preferably 6.0 N or more, and the rate of change is preferably within a range of −20 to 20%.

### [DMA Measurement (Dynamic Viscoelasticity Measurement)]

The composition was poured into a jig which was set to have 0.5 mm in thickness×10 mm in width×50 mm in length, and defoaming was performed. The composition was irradiated with ultraviolet ray (main wavelength: 365 nm) so that an accumulated light quantity was 30 kJ/m² by using a high-pressure mercury lamp with a belt-conveyer-type irradiation apparatus. Then, the cured product was cut to a strip with 10 mm in width to produce a test piece. The test piece was attached to a jig with a tensile mode, a storage elastic modulus (E′), a loss elastic modulus (E″), and tan δ (E″/E′) were measured, and a temperature at a maximum value of tan δ was specified as “Peak top temperature (° C.)”. The peak top temperature is preferably 0° C. or lower.

The evaluation results are shown in the following Table 2.

TABLE 2

| | | Example | Example | Example | Example | Example | Comparative |
|---|---|---|---|---|---|---|---|
| Test item | | 1 | 2 | 3 | 4 | 5 | Example 1 |
| Appearance | before curing | milky white | milky white | milky white | milky white | milky white | milky white |
| | after curing | milky white | milky white | milky white | milky white | milky white | milky white |
| Viscosity (Pa · s) | | 32 | 29 | 30 | 30 | 31 | 26 |
| Thick-film curability (mm) | | 8 | 8 | 8 | 8 | 8 | 8 |
| Tixotropic ratio | | 5.2 | 4.8 | 5.0 | 5.1 | 4.8 | 3.9 |
| Initial adhesion | Initial peeling state | Excellent | Excellent | Good | Excellent | Excellent | Poor |
| force | Initial strength (N) | 8.5 | 7.8 | 7.4 | 8.5 | 8.8 | 5.9 |
| Adhesion force | Strength after durability (N) | 8.4 | 6.5 | 6.4 | 9.7 | 9.4 | 3.5 |
| after durability | Rate of change (%) | −1 | −17 | −14 | 14 | 7 | −41 |

| | | | | | | |
|---|---|---|---|---|---|---|
| Peak top temperature (° C.) | −3.3 | −7.5 | −12 | −0.6 | −11.7 | −15 |

| | | Comparative | Comparative | Comparative | Reference |
|---|---|---|---|---|---|
| Test item | | Example 2 | Example 3 | Example 4 | Example 1 |
| Appearance | before curing | milky white | milky white | milky white | milky white |
| | after curing | milky white | milky white | milky white | milky white |
| Viscosity (Pa · s) | | 29 | 26 | 45 | 35 |
| Thick-film curability (mm) | | 8 | 8 | 8 | 8 |
| Tixotropic ratio | | 4.3 | 3.8 | 6.1 | 4.3 |
| Initial adhesion | Initial peeling state | Poor | Poor | Poor | Poor |
| force | Initial strength (N) | 8.5 | 7.0 | 6.0 | 7.6 |
| Adhesion force | Strength after durability (N) | 3.9 | 4.2 | 4.0 | 6.4 |
| after durability | Rate of change (%) | −54 | −40 | −33 | −16 |

| | | | | |
|---|---|---|---|---|
| Peak top temperature (° C.) | −12 | −0.5 | −18 | 7.2 |

With comparing Examples 1 to 5 and Comparative Examples 1 to 4, there are no differences in the appearance and the thick-film curability, but there is a clear difference in the initial peeling state. The initial peeling state of “Excellent” or “Good” can prevent leakage on the interface with the adherend. The adhesion force after durability in Examples 1 to 5, which are small absolute values of the rate of change s, is found to be favorable durability after pressing the cured product. Furthermore, the peak top temperature in Examples 1 to 5 is 0° C. or lower, and thereby the photocurable compositions of Examples 1 to 5 are estimated to yield a better initial peeling state.

Specifically, when the cured product obtained from the composition is used as the sealing agent, it is expected that the sealing agent can follow an adherend having low planarity.

### INDUSTRIAL APPLICABILITY

The sealing agent using the photocurable composition of the present invention exhibits favorable adhesion force to an adherend, and a high water-barrier property and a high helium-barrier property. Therefore, the sealing agent is useful for a sealing cover of a housing of a hard disk drive, and sealing agents for other electric and electronic components and an on-site formable gasket (gasket cured by applying before assembling).

The present application is based on Japanese Patent Application No. 2021-120077, filed on Jul. 21, 2021, and the disclosed content is entirely incorporated by reference.

1. A photocurable composition, comprising the following components (A) to (D), wherein a content of a monomer having an alicyclic structure and a (meth)acryloyl group is 6 to 20 mass % based on 100 mass % of a total amount of the component (C):
component (A): a polyisobutylene compound having a (meth)acryloyl group in a molecule;
component (B): a urethane-modified (meth)acrylate oligomer, excluding the component (A);
component (C): a monomer having a (meth)acryloyl group, excluding the component (A) and the component (B); and
component (D): photoinitiator.

2. The photocurable composition according to claim 1, wherein a total content of the component (B) is 1 to 50 parts by mass and a total content of the component (C) is 50 to 300 parts by mass, based on 100 parts by mass in total of the component (A).

3. The photocurable composition according to claim 1, wherein the alicyclic structure is a cyclic hydrocarbon group composed only of carbon atoms and hydrogen atoms.

4. The photocurable composition according to claim 1, wherein the alicyclic structure is at least one group selected from the group consisting of an isobornyl group, a dicyclopentenyl group, and a dicyclopentanyl group.

5. A cured product obtained by curing the photocurable composition according to claim 1 with light irradiation.

6. The cured product according to claim 5, wherein a peak top temperature of tan δ in a dynamic viscoelasticity measurement is 0° C. or lower.

7. A sealing agent comprising the photocurable composition according to claim 1.

8. The sealing agent according to claim 7, wherein the sealing agent is used for a hard disc drive cover seal.
